(19) United States
(12) Patent Application Publication
(10) Pub. No.: US 2011/0266685 A1
(43) Pub. Date: Nov. 3, 2011

(54) Semiconductor Device Comprising Sophisticated Conductive Elements in a Dielectric Material System Formed by Using a Barrier Layer

(75) Inventors: Dmytro Chumakov, Dresden (DE); Volker Grimm, Langebrueck (DE)

(73) Assignee: GLOBALFOUNDRIES INC., Grand Cayman (KY)

(21) Appl. No.: 12/963,707

(22) Filed: Dec. 9, 2010

(30) Foreign Application Priority Data
Apr. 30, 2010 (DE) 10 2010 028 463.7

(51) Int. Cl. H01L 23/52; H01L 21/768

(52) U.S. Cl. 257/773; 438/643; 257/E21.577; 257/E23.141

(57) ABSTRACT

An efficient patterning strategy may be applied when etching through a dielectric material system on the basis of two different etch chemistries. To this end, a conductive etch stop or barrier material may be formed in the opening prior to etching through the further dielectric layer of the material system, thereby substantially preserving the initial critical dimensions and avoiding etch damage. Thus, superior contact openings, via openings and the like may be formed on the basis of well-established etch chemistries.

### BACKGROUND OF THE INVENTION

1. Field of the Invention

Generally, the present disclosure relates to integrated circuits, and, more particularly, to “vertical” conductors formed in a dielectric material system in high aspect ratio openings of metallization layers, contact levels and the like.

2. Description of the Related Art

In an integrated circuit, a very large number of circuit elements, such as transistors, capacitors, resistors and the like, are formed in or on an appropriate substrate, usually in a substantially planar configuration. Due to the large number of circuit elements and the required complex layout of advanced integrated circuits, the electrical connections of the individual circuit elements are generally not established within the same level on which the circuit elements are manufactured. Typically, such electrical connections are formed in one or more additional wiring layers, also referred to as metallization layers, contact structures and the like. These wiring layers generally include metal-containing features, such as metal lines and/or vertical or inter-level connections, also referred to as vias, contacts and the like, that are filled with an appropriate metal. The vertical interconnect features provide electrical connection between two neighboring stacked device levels, such as neighboring metallization layers, a contact structure and the very first metallization layer, and the like.

Due to the ongoing demand for shrinking the feature sizes of highly sophisticated semiconductor devices, highly conductive metals, such as copper and alloys thereof, in combination with a low-k dielectric material, have become frequently used alternatives in the formation of metallization layers. Typically, a plurality of metallization layers stacked on top of each other are necessary to realize the connections between all internal circuit elements and I/O (input/output), power and ground pads of the circuit design under consideration. For extremely scaled integrated circuits, the signal propagation delay, and thus the operating speed of the integrated circuit, may no longer be limited by the semiconductor elements, such as transistors and the like, but may be restricted, owing to the increased density of circuit elements requiring an even more increased number of electrical connections, by the close proximity of the metal lines, since the line-to-line capacitance is increased, which is accompanied by the fact that the metal lines have a reduced conductivity due to a reduced cross-sectional area. For this reason, traditional dielectrics such as silicon dioxide (k>5) and silicon nitride (k>7) are replaced by dielectric materials having a lower permittivity, which are, therefore, also referred to as low-k dielectrics, having a relative permittivity of 3 or less. The reduced permittivity of these low-k materials is frequently achieved by providing the dielectric material in a porous configuration, thereby achieving a k-value of significantly less than 3.0. Due to the intrinsic properties, such as a high degree of porosity, of the dielectric material, however, the density and mechanical stability or strength may be significantly less compared to the well-approved dielectrics silicon dioxide and silicon nitride.

When forming sophisticated metallization systems including, for instance, copper-based metal features, a so-called damascene or inlaid technique is usually used due to copper's characteristic of not forming volatile etch products when being exposed to well-established anisotropic etch chemistries. In the inlaid technique, therefore, the dielectric material is patterned to receive trenches and/or vias, which are subsequently filled with a conductive material, such as copper, by any appropriate deposition technique. Moreover, typically, a conductive barrier layer may be applied in combination with copper material so as to enhance adhesion and reduce copper diffusion into any sensitive device areas. As indicated above, the reduced critical dimensions of transistor elements of 50 nm and significantly less in sophisticated applications also require a corresponding adaptation of the critical dimensions in the metallization system of the semiconductor device. Therefore, similar critical dimensions have to be implemented in the metallization system, while, on the other hand, the thickness of the metal features may not be arbitrarily reduced in view of obtaining a certain desired cross-sectional area of, for instance, metal lines. Consequently, the vias or vertical interconnect features may be formed on the basis of openings having an aspect ratio (height/width) of 5 and higher, thereby requiring sophisticated lithography and etch techniques. The etch process may typically be performed on the basis of an appropriate material system, i.e., a material, such as the actual interlayer dielectric material in combination with an etch stop material, that may provide superior etch controllability. On the other hand, the etch stop layer requires a further etch step during the complex patterning process in order to open the etch stop material and connect to the underlying metal region. The additional etch step for opening the etch stop layer is typically performed based on an appropriately selected etch chemistry, which, however, may frequently have a significantly reduced selectivity with respect to the previously etched interlayer dielectric material, thereby generating additional etch damage in exposed portions of the interlayer dielectric material.

As explained above, frequently, sophisticated dielectric materials having a reduced dielectric constant have to be used in critical metallization systems, wherein these low-k and ultra low-k (ULK) materials may suffer from an increased etch damage, in particular during the etch step for opening the etch stop layer, due to the reduced etch selectivity. Consequently, a significant material modification at exposed inner sidewall surface areas of the openings may occur and an increase of the initial critical dimension is also frequently observed. Both effects may, however, significantly contribute to a less predictable and inferior overall performance of the metallization system, in particular in semiconductor devices, in which reduced dimensions have to be used in the metallization system.

Similarly, in the contact level of semiconductor devices, the critical dimensions of contact elements have to be adapted to the reduced size of circuit elements, such as transistors, thereby also requiring sophisticated etch techniques for forming contact openings in the dielectric material system of the contact level. Since a modification of the critical dimensions in the contact level may result in severe contact failures, such as increased leakage currents, short circuits and the like, significant yield losses may be observed in sophisticated semiconductor devices.

With reference to FIGS. 1a-1e, conventional process strategies will now be described in more detail in order to more clearly identify problems associated with the formation of contact openings or via openings in sophisticated semiconductor devices.

FIG. 1a schematically illustrates the cross-sectional view of a semiconductor device 100 in an advanced manufacturing stage. As illustrated, the device 100 comprises a substrate 101, such as a silicon substrate or generally a semiconductor substrate, an insulating substrate and the like. A semiconductor layer 102, such as a silicon layer, a silicon/germanium layer and the like, is formed above the substrate 101 and is appropriately configured to enable the fabrication of semiconductor-based circuit elements 150, such as field effect transistors and the like. The semiconductor layer 102 may comprise a plurality of active regions 102A, which are to be understood as semiconductor regions in which PN junctions of one or more transistors are implemented. Moreover, the semiconductor layer 102 may comprise a plurality of isolation structures 102B, such as shallow trench isolations, which laterally delineate the active regions 102A. The transistors 150 may represent field effect transistors comprising a gate electrode structure 154, which may in turn comprise a gate dielectric material 154A in combination with any appropriate electrode material 154B, such as polysilicon, polysilicon in combination with metal silicides, electrode metals, metal-containing electrode materials and the like. Similarly, the gate dielectric material 154A may comprise any appropriate materials, such as silicon dioxide, silicon oxynitride and high-k dielectric materials in the form of hafnium oxide, hafnium silicon oxide, zirconium oxide and the like.

As indicated above, a critical dimension of the transistor 150 may be represented by a length of the gate electrode structures 154, as indicated by 154L. For example, in sophisticated applications, the length 154L may be 50 nm and significantly less, such as 30 nm and less in planar transistor architectures. Moreover, drain and source regions 151 may be formed in the active region 102A and may comprise contact areas 152, for instance in the form of a metal silicide and the like. The circuit elements 150, i.e., the semiconductor layer 102 and the gate electrode structures 154, may also be referred to as a “device level” of the semiconductor device 100, which has to be connected to a metallization system that is still to be formed above the device level of the device 100. Furthermore, in the manufacturing stage shown, a contact structure or contact level 120 is provided and is represented by a dielectric material system, which may comprise two or more materials, such as a first dielectric layer 121 and a second dielectric layer 122. For instance, the dielectric layer 121 may be provided in the form of a silicon nitride material, which may serve several purposes, such as an etch stop material, a strain-inducing material and the like. Furthermore, the dielectric layer 122 may typically be comprised of silicon dioxide, while, however, any other appropriate material may be used, such as low-k dielectric materials and the like.

The semiconductor device 100 as illustrated in FIG. 1 a may be formed on the basis of the following process techniques. The active regions 102A and the isolation structure 102B may be formed on the basis of well-established process techniques by forming trenches in the semiconductor layer 102 and refilling the trenches with any appropriate dielectric material, such as silicon dioxide, silicon nitride and the like. In this manner, the lateral dimensions of the active region 102A may be determined. Prior to or after forming the isolation structure 102B, the basic doping in the active region 102A is provided on the basis of appropriate implantation and masking regimes. Next, the gate electrode structures 154 may be formed, for instance, by providing an appropriate material layer stack and patterning the same based on sophisticated lithography and etch techniques, followed by the formation of the drain and source regions 151, which may be accomplished by using the gate electrode structure 154 and the spacer structure 153 as an implantation mask. Thereafter, if required, the contact areas in the form of the metal silicide 152 may be formed, followed by the deposition of the dielectric material system 120, for instance, by depositing the first layer 121 using, for instance, plasma enhanced chemical vapor deposition (CVD) techniques, followed by the deposition of the second dielectric layer 122 using, for example, sub-atmospheric CVD, high density plasma CVD and the like. Thereafter, the dielectric material of the system 120 may be planarized, for instance, by chemical mechanical polishing (CMP) and thereafter a complex patterning regime has to be applied so as to form contact openings 123 in the dielectric material system 120. A corresponding patterning regime will be described later on with reference to FIG. 1c.

FIG. 1b schematically illustrates the semiconductor device 100 in a further advanced manufacturing stage, in which contact elements 123 are provided in the dielectric material system of the contact level 120 so as to connect to the contact areas 152 and also to connect to a metallization system. The metallization system may comprise a plurality of metallization layers, of which a metallization layer 140 and a metallization layer 160 are illustrated in FIG. 1b. For example, the metallization layer 140 may comprise a dielectric material 141 and metal regions or metal lines 144, such as aluminum lines, copper-based metal lines in combination with a conductive barrier material (not shown) and the like. Similarly, the metallization layer 160 comprises, in the manufacturing stage shown, a dielectric material system in the form of a first dielectric material 161, which may also be considered as an etch stop layer and/or a dielectric cap layer, followed by the actual interlayer dielectric material 162, which is frequently provided in the form of a low-k or ULK material. Also, in this case, via openings 163 are to be formed in the material system of the metallization layer 160 so as to connect to the underlying metal regions 144. The metallization system may be formed on the basis of any appropriate process technique, for instance using sophisticated inlaid techniques, in which the dielectric material system of a corresponding metallization layer is to be patterned so as to receive via openings, such as the openings 163, which are subsequently filled with an appropriate conductive material.

FIG. 1c schematically illustrates a portion of the semiconductor device 100, in which a dielectric material system comprising at least two different dielectric materials is to be patterned so as to form an opening therein. For convenience, it may be referred to the contact level 120 or the metallization layer 160 as a dielectric material system, which may comprise the first dielectric layer 121 or 161 and the second dielectric layer 122 or 162. In both cases, openings of high aspect ratio have to be formed in the dielectric material system, wherein a high degree of etch fidelity and, thus, predictability of the resulting critical dimensions may be an important aspect in view of the finally achieved electrical performance of the semiconductor device 100. For this purpose, an etch mask 103 is typically formed on or above the dielectric material system 120/160 and may comprise a mask opening 103A that defines the lateral position and size of an opening to be formed in the underlying dielectric layers. The etch mask 103 may comprise, for instance, a resist material, or two or more resist layers, or any other materials, such as hard mask materials and the like, as are required for providing sufficient etch resistivity so as to etch through at least a significant portion of the layer 122 or 162. To this end, sophisticated lithography techniques and material deposition processes may be applied.

FIG. 1d schematically illustrates the semiconductor device 100 in a further advanced manufacturing stage. For convenience, it is referred to the dielectric material system 120, while analogous observations also apply for the metallization layer 160 as shown in FIG. 1c. The device 100 is exposed to a reactive etch atmosphere 104, which is established on the basis of a plasma ambient so as to obtain a substantially anisotropic etch behavior. For this purpose, a plurality of anisotropic etch recipes based on reactive components, such as fluorine, chlorine and the like, are well established in the art for a plurality of materials, wherein the etch chemistry used in the process 104 may typically have a significantly reduced removal rate for the material of the etch mask 103 and also for the dielectric layer 121, which may thus act as an efficient etch stop material. For example, silicon dioxide may be efficiently etched on the basis of a plurality of well-established etch chemistries selectively with respect to silicon nitride and a plurality of polymer materials. Similarly, many etch recipes have been established so as to etch through low-k dielectric materials or ULK materials, while using silicon nitride, nitrogen-enriched silicon carbide and the like as efficient etch stop materials. Consequently, during the etch process 104, an opening 123A is efficiently formed in the dielectric material 122, while the etch front may be efficiently stopped on or in the dielectric material 121, thereby providing superior controllability, for instance, for reliably exposing the material 121 within the opening 123A across the entire substrate and/or forming contact openings 123A to different height levels, such as to contact areas of gate electrode structures and active regions, as is for instance shown in FIGS. 1a and 1b.

FIG. 1e schematically illustrates the semiconductor device 100 during a further etch step 105, in which, typically, a different etch chemistry is to be used so as to efficiently etch through the layer 121. Consequently, during the etch process 105, inner surface areas 123S of the opening 123A are also exposed to the reactive etch atmosphere during the process 105, wherein, typically, the etch chemistry used may have a significantly lesser degree of selectivity with respect to the material 122. Consequently, depending on the lateral etch rates during the process 105, a significant material removal may occur within the material 122, thereby modifying the finally achieved critical dimension. Furthermore, in sophisticated low-k dielectric materials, significant etch damage may occur, i.e., a modification of a surface layer may be observed, which may impart different characteristics to the modified portion of the material 122, which in turn may result in a reduced performance of the resulting metallization system or contact structure. In particular, an increase of the initial critical dimension may require a corresponding design strategy so as to take into account increased overall dimensions, which, however, may limit the finally achieved packing density. Furthermore, the additional interaction of the etch chemistry of the process 105 with the exposed sidewall surface areas 123S may result in non-desired surface characteristics of the dielectric material 122. Consequently, upon refilling the contact opening or via opening 123 with an appropriate conductive material, such as tungsten, aluminum, copper, possibly in combination with a conductive barrier material, the inferior internal cross-sectional shape of the opening 123 in combination with the inferior surface characteristics caused by the etch step 105 may result in less efficient deposition conditions, which may also contribute to a reduced overall electrical performance and reliability of the resulting contact element or via.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present disclosure generally provides semiconductor devices and manufacturing techniques in which an enhanced patterning regime may be applied for forming openings in a dielectric material system comprising at least two materials of different etch behavior. To this end, a conductive etch stop material or barrier material may be applied in the opening prior to performing a second etch step for etching through a second dielectric layer on the basis of a different etch chemistry. The conductive barrier material or etch stop material may provide integrity of the sidewall surfaces of the opening during the subsequent etch process, thereby substantially maintaining the initial critical dimensions of the opening, while at the same time reliably “sealing” the exposed surface areas of the dielectric material, such as low-k dielectric materials, ULK materials, materials in contact levels and the like. The conductive etch stop layer or conductive barrier layer may be preserved to a high degree and may, thus, act, in combination with an additional fill material as an efficient conductive barrier of the conductive element to be formed in the dielectric material system under consideration. In some illustrative aspects, a further conductive barrier layer may be formed after etching through the entire dielectric material system, thereby also covering any lower sidewall surface areas of the underlying dielectric material of the material system, if required. On the other hand, the conductive etch stop or barrier material may contribute to an enhanced overall electrical performance and reliability of the resulting conductive element, such as a contact element or a via, contrary to some conventional approaches, in which a dielectric liner, such as a silicon dioxide material, may frequently be provided in critical contact or via openings in order to reduce the overall etch damage. Consequently, critical dimensions may be implemented with superior reliability into a dielectric material system and may allow reduced overall critical dimensions, thereby contributing to superior packing density in sophisticated semiconductor devices.

One illustrative method disclosed herein comprises forming an opening in a dielectric material system that is formed above a substrate of a semiconductor device, wherein the dielectric material system comprises at least a first dielectric layer and a second dielectric layer. The method further comprises forming a first conductive barrier layer on inner sidewall surface areas in the opening. The method further comprises increasing a depth of the opening so as to extend through the dielectric material system in the presence of the conductive barrier layer. Furthermore, a second conductive barrier layer is formed in the opening and the opening is filled with a conductive material.

A further illustrative method disclosed herein comprises forming a conductive etch stop material on inner sidewall surfaces of an opening that is formed in a dielectric material system, which in turn is formed above a semiconductor layer of a semiconductor device. The method additionally comprises increasing a depth of the opening by using the conductive etch stop material for preserving integrity of the inner sidewall surfaces. Moreover, the method comprises filling the opening with a metal-containing conductive material.

One illustrative semiconductor device disclosed herein comprises a dielectric material system comprising at least a first dielectric layer and a second dielectric layer formed above the first dielectric layer, wherein the dielectric material system is formed above a device level comprising transistors having critical dimensions of approximately 50 nm or less. The semiconductor device further comprises a conductive element extending through the dielectric material system and comprising a first conductive barrier layer formed so as to be in direct contact with a portion of the second dielectric layer without extending to the first dielectric layer.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b schematically illustrate cross-sectional views of a semiconductor device during various manufacturing stages, in which an opening has to be formed in a contact level and a metallization layer, respectively on the basis of a sophisticated etch sequence, according to conventional strategies;

FIGS. 1c-1e schematically illustrate cross-sectional views of the etch sequence, according to conventional approaches;

FIGS. 2a-2e schematically illustrate cross-sectional views of a semiconductor device during various manufacturing stages in forming an opening in a dielectric material system, for instance in a contact level or a metallization layer as shown in FIGS. 1a and 1b, respectively, on the basis of a conductive etch stop layer or barrier layer provided prior to opening an etch stop material of the dielectric material system, according to illustrative embodiments;

FIG. 2f schematically illustrates a cross-sectional view of the semiconductor device according to embodiments in which a second conductive barrier layer may be provided prior to forming a metal-containing material in the opening;

FIG. 2g schematically illustrates a cross-sectional view of the semiconductor device in a further advanced manufacturing stage; and

FIGS. 2h-2k schematically illustrate cross-sectional views of the semiconductor device during various manufacturing stages, in which a trench and a via opening may be formed on the basis of a conductive barrier material, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure provides semiconductor devices and methods in which an opening may be efficiently formed in a dielectric material system by reducing the exposure of a portion of the dielectric material system to the reactive etch ambient. To this end, the opening may be formed so as to extend to a specific depth and thereafter a conductive barrier material or etch stop material may be formed on inner sidewall surface areas of the opening so as to provide superior etch resistivity during the further etch process sequence. That is, during the subsequent etch phase, the previously formed opening, i.e., the corresponding sidewalls, may be efficiently sealed and, thus, protected with respect to the reactive etch ambient, thereby avoiding the modification of the material characteristics and an increase of the initially implemented lateral size of the opening. For example, a critical opening having a high aspect ratio may be formed so as to extend through the upper dielectric layer, such as an interlayer dielectric material, and an underlying dielectric material, such as an etch stop layer, may then be efficiently opened on the basis of an appropriate etch chemistry, while the initially formed sidewall surface areas may be appropriately protected by the conductive etch stop or barrier material. It is well known that a plurality of metal-containing conductive materials, such as tantalum, tantalum nitride, titanium, titanium nitride and the like, exhibit superior etch resistivity with respect to a plurality of wet chemical and plasma assisted etch recipes, many of which may typically be used for opening dielectric etch stop materials, such as silicon nitride, silicon dioxide and the like, during a complex patterning sequence for forming contact openings, via openings and the like. Consequently, the initial lateral size of the opening may be substantially preserved, since the conductive material may represent a part of the conductive fill material that has to be provided in the opening. In some illustrative embodiments, a second conductive barrier material may be formed prior to depositing the actual fill material, if coverage of lower portions of the final opening is required. Consequently, reduced critical dimensions may be achieved on the basis of well-established etch chemistries, while at the same time avoiding or at least significantly suppressing undue damaging of sensitive dielectric materials, such as low-k materials, ULK materials and the like.

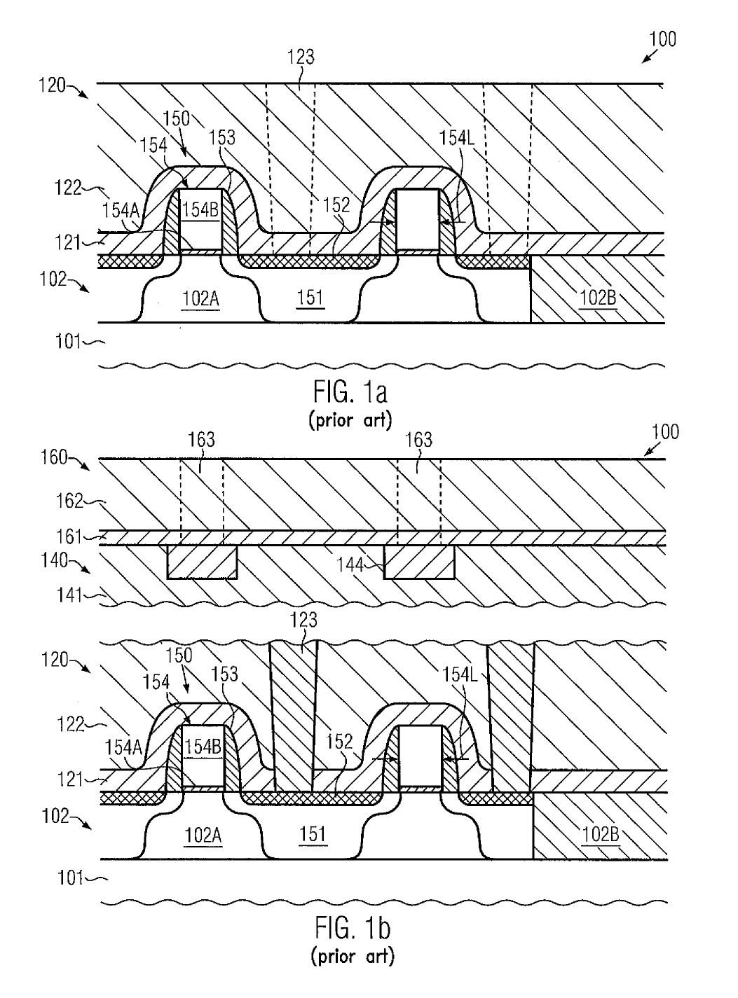

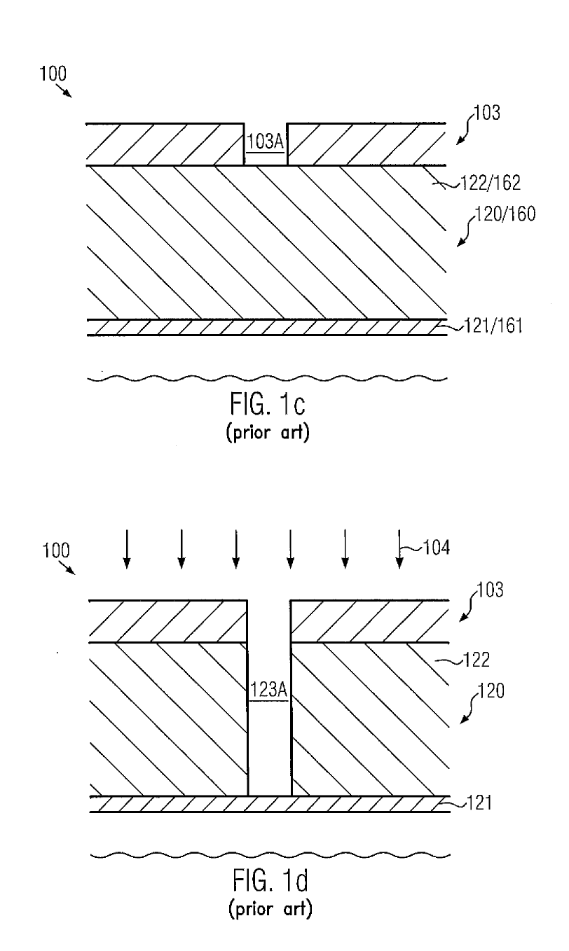

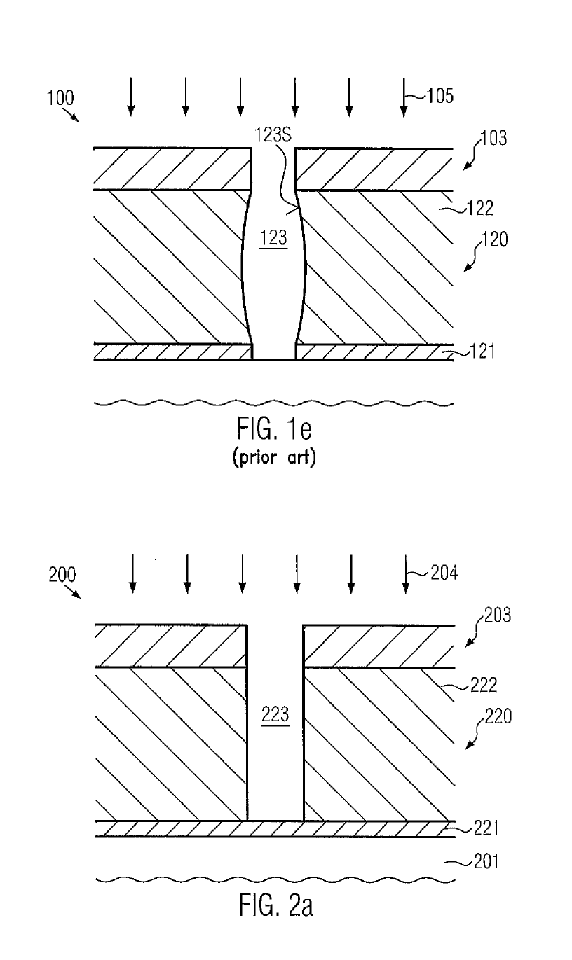

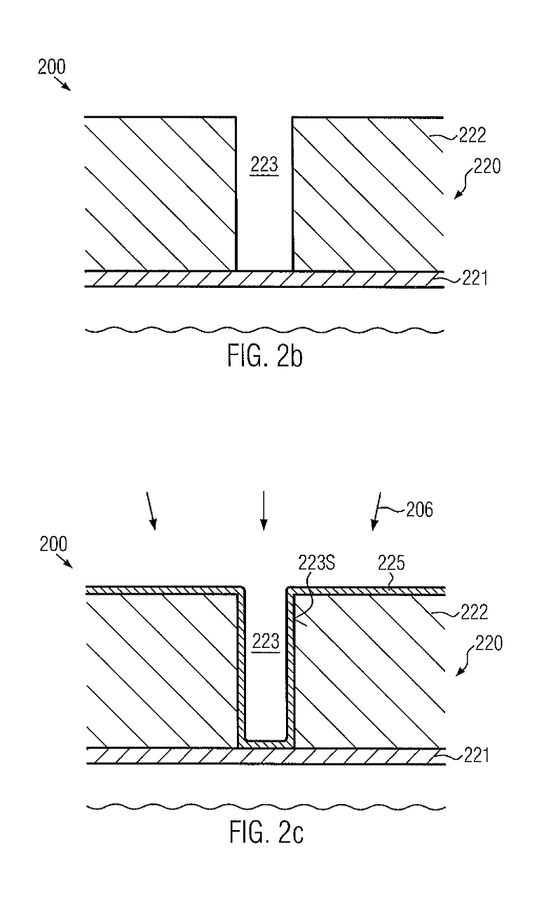

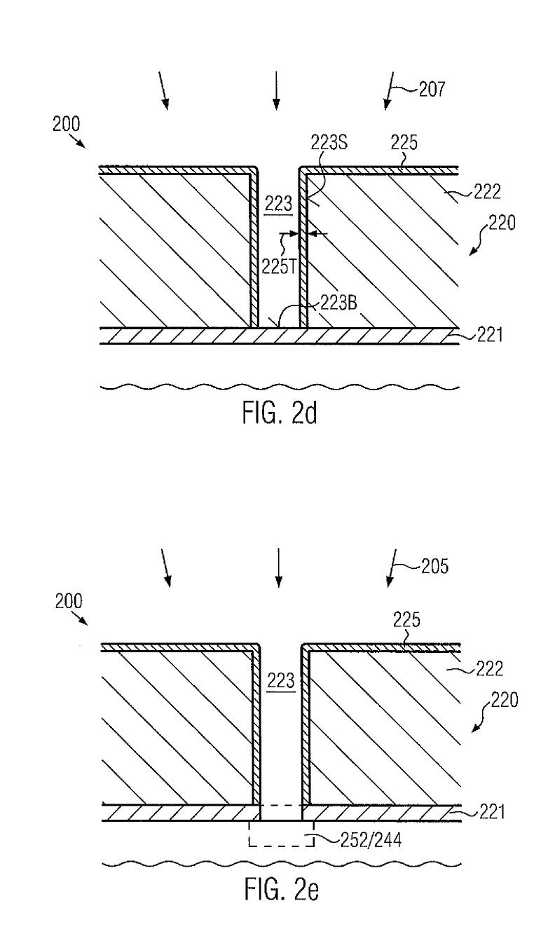

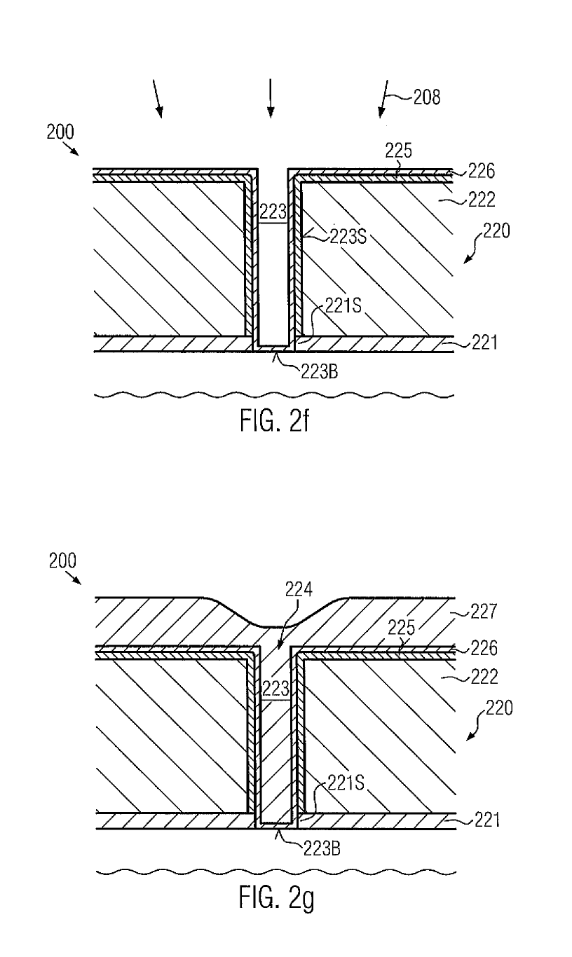

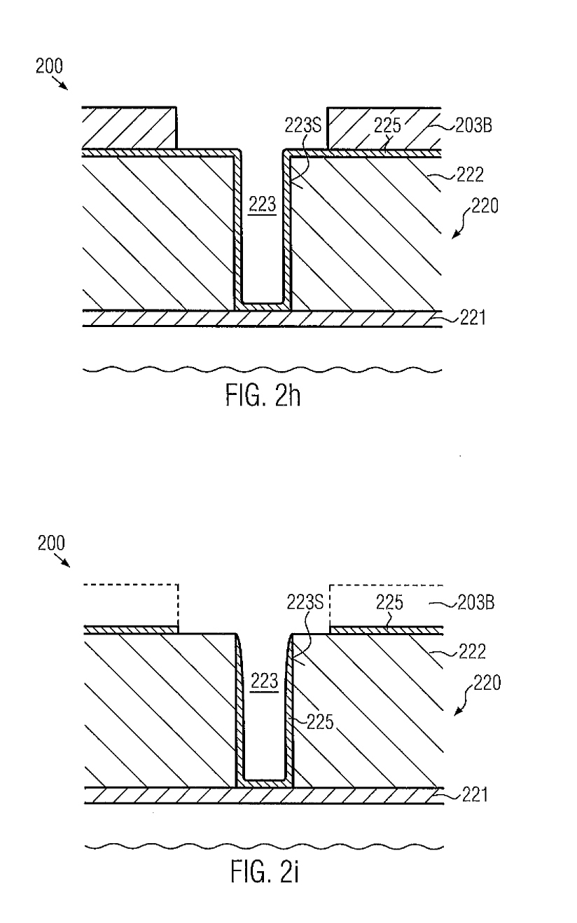

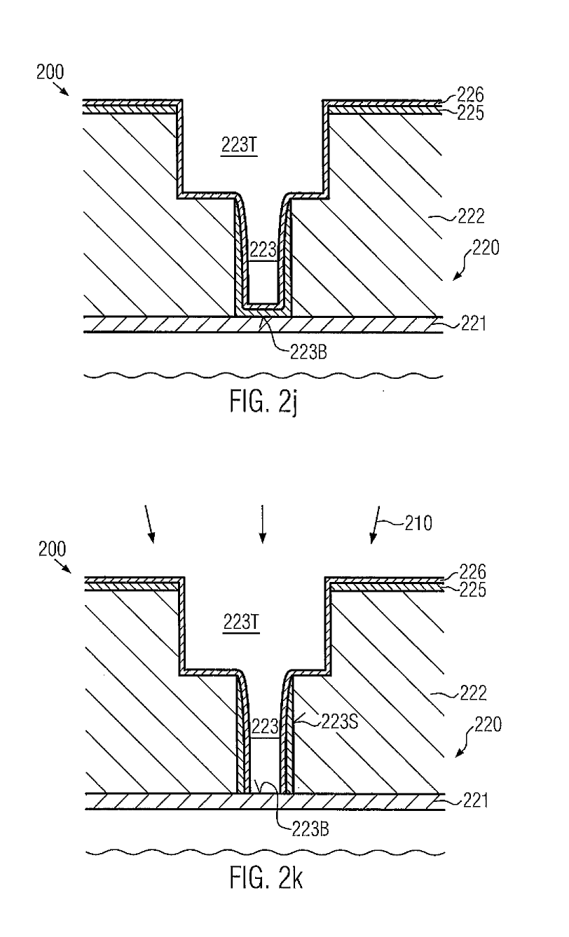

With reference to FIGS. 2a-2k, further illustrative embodiments will now be described in more detail, wherein reference is also made to FIGS. 1a-1e, and in particular to FIGS. 1a and 1b, which refer to a contact level and a metallization system, respectively.

FIG. 2a schematically illustrates a cross-sectional view of a semiconductor device 200 in a certain manufacturing stage, in which a dielectric material system 220 is to be patterned so as to receive an opening, such as a contact opening, a via opening and the like. The dielectric material system 220 may be formed above a substrate 201, which may represent any appropriate carrier material including a semiconductor layer, as is, for instance, also described above with reference to the semiconductor device 100 when referring to FIGS. 1a and 1b. For example, in some illustrative embodiments, the dielectric material system 220 may be the dielectric material of a contact level, such as the contact level 120 of the device 100 in FIG. 1a, while, in other cases, the system 220 may represent the dielectric materials of a metallization layer, such as the metallization layer 160 of the device 100 as shown in FIG. 1b. Consequently, a corresponding device level may be provided below the dielectric material system 220 and may comprise any appropriate circuit elements, such as transistors and the like, as is also previously described with reference to the transistors 150 in FIGS. 1a and 1b. Consequently, any criteria and characteristics of these components may also apply to the device 200 and the description of any such components is omitted here.

The material system 220 may comprise a first dielectric layer 221 and a second dielectric layer 222, which may typically differ in material composition and may, thus, have a significantly different etch behavior. For example, as also previously discussed with reference to the device 100, the dielectric layer 221 may comprise silicon nitride, nitrogen-enriched silicon carbide and the like, possibly provided with a high internal stress level so as to modify the electrical performance of any underlying circuit components, such as transistors and the like. In other cases, the dielectric layer 221 may itself represent a material system comprising two or more individual material layers. The dielectric layer 222, which may be considered as the actual interlayer dielectric material, may be comprised of silicon dioxide, for instance, in the case of a contact level, while, in other cases, sophisticated low-k dielectric materials or ULK materials may be used, as also previously discussed. Furthermore, an etch mask 203, such as a resist material or a combination of resist materials, a hard mask material and the like, may be provided so as to define the lateral position and the lateral size of an opening 223 to be formed in the dielectric material system 220.

The semiconductor device 200 may be formed in accordance with any appropriate process techniques as is, for instance, also described above with reference to the semiconductor device 100. After providing the etch mask 203, the device 200 may be exposed to an etch process 204 that is designed to etch through the material 222, thereby forming the opening 223, which may extend to the first dielectric layer 221, which may, thus, act as an efficient etch stop material, as is also previously described. It should be appreciated that the etch mask 203 may be formed on the basis of design strategies in which an additional increase of the critical dimensions of the opening 223 during the further patterning of the system 220 may not need to be taken into consideration due to the superior process conditions during the further processing, as will be described later on. Consequently, openings may be provided with reduced lateral offset, which may, thus, contribute to an overall increased packing density.

FIG. 2b schematically illustrates the semiconductor device 200 in a further advanced manufacturing stage, in which the etch mask 203 (FIG. 2a) may be removed, for instance, on the basis of any wet chemical and/or plasma assisted etch recipes, possibly in combination with a cleaning process, so as to prepare the dielectric material 222 for the deposition of a conductive material.

FIG. 2c schematically illustrates the semiconductor device 200 during a deposition process 206, such as a sputter deposition process, a CVD-like process and the like, in which a conductive material layer 225, which may also be referred to as an etch stop layer or a barrier layer, may be formed on the dielectric material 222 and, thus, on inner sidewall surface areas 223S of the opening 223. It should be appreciated that a plurality of conductive materials, such as titanium, titanium nitride, tantalum, tantalum nitride and the like, are well established in semiconductor production techniques, wherein these materials may provide superior etch resistivity with respect to a plurality of well-established etch recipes. Moreover, corresponding conductive metal-containing materials may frequently be efficiently used as barrier materials in combination with sophisticated metal materials, such as copper, tungsten and the like, in order to provide superior adhesion, diffusion blocking effect and the like. It should be appreciated that, if required, the conductive etch stop or barrier layer 225 may be provided in the form of two distinct layers, such as a titanium nitride layer and a titanium layer, and the like, if considered appropriate for the further processing of the device 200. Furthermore, a thickness of the layer 225 may be appropriately selected so as to preserve a desired minimum thickness at the sidewall surface areas 223 S after removing the material of the layer 225 from the bottom of the opening 223. For example, the layer 225 may be provided with a thickness of approximately 3-20 nm, depending on the overall size of the opening 223 and the process conditions during the subsequent processing of the device 200.

FIG. 2d schematically illustrates the semiconductor device 200 in a further advanced stage, in which a selective material removal process 207 may be applied so as to substantially expose the dielectric material 221 at the bottom 223B of the opening 223. The removal process 207 may be applied on the basis of a sputter deposition technique, in which substantially inert particles, such as noble gas atoms and the like, may preferably be accelerated towards horizontal surface portions. On the other hand, the material removal at the sidewalls 223S is significantly less pronounced so that a desired minimum width 225T may be reliably preserved upon exposing the bottom 223B of the opening 223. It should be appreciated that appropriate process parameters of the process 207 may be readily determined on the basis of experiments starting from well-established sputter etch recipes. Consequently, after the removal process 207, the sidewall surface areas 223S are reliably “sealed” by material of the layer 225 having the thickness 225T in the range 2-20 nm, or even more, depending on the initial layer thickness. Thus, the material characteristics of the surface areas 223S and the lateral size of the opening 223 as initially defined after the etch process 204 (FIG. 2a), possibly in combination with any cleaning processes (FIG. 2b), may be preserved on the basis of the material layer 225 and may not be substantially modified during the further processing due to the high etch resistivity of the layer 225. On the other hand, the conductivity of the material 225 may contribute to the overall electrical performance, contrary to other approaches in which dielectric materials may frequently be used for coating the inner sidewall surface areas of critical openings.

FIG. 2e schematically illustrates the semiconductor device 200 during a further etch process 205, which may be performed on the basis of an appropriate etch recipe so as to efficiently etch through the dielectric material 221, wherein the layer 225 may act as an efficient etch stop material. Consequently, the depth of the opening 223 may be increased so as to connect to a lower-lying region, such as a contact region 252 of a transistor or to a metal region 244 of a lower-lying metallization layer, as is also previously described with reference to FIGS. 1a and 1b, respectively, when referring to the semiconductor device 100. Consequently, any appropriate etch chemistry may be used during the process 205, for instance plasma assisted etch recipes, wet chemical recipes, if a certain degree of under-etching may be considered appropriate, and the like. For example, well-established etch chemistries may be used for the etch processes 204 (FIG. 2a) and the etch process 205 without unduly affecting the dielectric material 222 due to the presence of the conductive etch stop or barrier layer 225.

In some illustrative embodiments, a barrier material may not be required in contact with the underlying regions 252, 244, in particular when the dielectric material 221 may also provide desired barrier characteristics, for example, if a copper material may have to be filled into the opening 223 so as to connect to the regions 252, 244, and a silicon nitride material may provide sufficient diffusion blocking capabilities so as to avoid undue diffusion of copper material into the dielectric material. Consequently, in such embodiments, the further processing may be continued by depositing any appropriate material, such as a catalyst material, a seed material and the like, and filling the opening 223 with any appropriate conductive material, such as copper and the like. In this case, the material layer 225 within the opening 223 in combination with the dielectric material 221 may act as efficient barrier materials, for instance in the form of tantalum, tantalum nitride and the like, in combination with silicon nitride, nitrogen-enriched silicon carbide and the like.

FIG. 2f schematically illustrates the semiconductor device 200 according to further illustrative embodiments in which a barrier material may also be provided at the bottom 223B and also at sidewall surface areas 221S of the dielectric material 221. To this end, a further deposition process 208 may be performed so as to provide a second conductive barrier material 226, having any desired material composition. Consequently, the materials 225 and 226 may impart the desired overall material characteristics at the sidewall surface areas 223S across the dielectric material 222, thereby, for instance, compensating for any material loss of the layer 225 during the preceding processing. Hence, any desired thickness may be provided for the layer 226 on the basis of any appropriate deposition techniques, such as sputter deposition, electrochemical deposition, CVD-type deposition and the like. In other cases, the material layer 226 may be provided in the form of a seed layer so as to initiate the subsequent deposition of the actual fill material, for instance in the form of tungsten, aluminum, copper and the like.

FIG. 2g schematically illustrates the device 200 in a further advanced stage in which a conductive fill material 227, such as copper, tungsten, aluminum, silver and the like, may be provided so as to reliably fill the opening 223, which may be accomplished on the basis of electrochemical deposition techniques, CVD and the like. Consequently, the opening 223 in combination with at least the conductive etch stop material or barrier material 225 may form a conductive element 224, such as a contact element in a contact level or a via in a metallization layer, as is previously described with reference to the device 100, however, with a significantly reduced degree of etch damage in the material 222 and with superior critical dimensions. Moreover, in some illustrative embodiments, as, for instance, shown in FIG. 2g, the conductive element 224 may also comprise the second barrier material 226, which may be formed on the sidewall surface areas 221 S of the dielectric material 221 and at the bottom 223B of the opening 223. Thereafter, any excess material of the layers 227 and 225, and possibly of the layer 226, if provided, may be removed on the basis of any appropriate removal techniques, such as CMP, electro-etching and the like.

FIG. 2h schematically illustrates the semiconductor device 200 according to further illustrative embodiments. As illustrated, the opening 223 may be formed in the dielectric layer 222 so as to extend to or into the dielectric layer 221, as is also previously explained, wherein the conductive barrier layer or etch stop layer 225 may be formed on any exposed surface areas. Furthermore, an etch mask 203B may be provided so as to define the lateral position and size of a trench to be formed in the dielectric material 222. For example, the etch mask 203B may define a metal line to be formed in the dielectric material system 220, for example when representing a metallization layer of a semiconductor device, as previously explained with reference to FIG. 1b. On the basis of the etch mask 203B, the layer 225 may be patterned, for instance, by sputter etching and the like in order to remove material, preferably from horizontal device areas, while at the same time preserving a significant portion at the sidewall surface areas 223S.

FIG. 2i schematically illustrates the device 200 after the above-described process sequence, wherein, if considered appropriate, the etch mask 203B may be removed, which may be accompanied by a further cleaning process, if considered appropriate. Thus, the layer 225 may represent a “hard mask” on horizontal device areas of the dielectric material system 220, while the material of the layer 225 at the sidewall areas 223S may preserve integrity of the layer portion of the dielectric material 222 during the subsequent processing. That is, upon performing an anisotropic etch process, a trench may be formed in the dielectric material 222 using at least the material 225 as an etch mask, possibly in combination with the etch mask 203B.

FIG. 2j schematically illustrates the device 200 in a further advanced stage, in which a trench opening 223T is formed above the opening 223 having a desired lateral dimension and depth in accordance with overall design requirements. Moreover, a further conductive barrier material 226 may be formed within the openings 223, 223T, wherein, typically, an increased layer thickness may be obtained at the bottom of the trench 223T, compared to the bottom 223B, since the opening 223 may have significantly smaller lateral dimensions, compared to the trench 223T. Due to the presence of the layer 225, a pronounced thickness of the layer 226 within the opening 223 may not be required, so that the material of the layer 226 may be readily removed from the bottom of the opening 223.

FIG. 2k schematically illustrates the device 200 during a directional etch process 210, such as a sputter etch process, in which the bottom 223B of the opening 223 may be exposed, while a portion of the material 226 may still be preserved within the trench opening 223T and also within the opening 223 at the sidewall surface areas 223S thereof.

Consequently, the processing may be continued by performing a further etch process, such as the etch process 205 (FIG. 2e), in order to etch through the dielectric layer 221, wherein the layer 226 may preserve integrity of the trench opening 223T, while the material 226 and 225 in combination may preserve integrity of the opening 223. After etching through the dielectric layer 221, the further processing may be continued, for instance, by depositing a desired fill material, for instance, when an additional coverage of exposed sidewall surface areas of the dielectric material 221 may not be required. In other cases, a further barrier material may be deposited, followed by the deposition of the actual fill material. Thus, dual inlaid strategies may be efficiently applied in sophisticated applications, wherein the initial critical dimensions may be preserved during the complex patterning sequence.

As a result, the present disclosure provides manufacturing techniques and semiconductor devices in which a dielectric material system may be patterned so as to receive critical openings, such as contact openings, via openings and the like, on the basis of at least two different etch chemistries, wherein integrity of a dielectric material may be preserved during at least the final etch step. To this end, a conductive barrier material or etch stop material may be formed within the opening after a first etch step so that material characteristics and the initial critical dimension may be preserved in the previously formed opening during the further processing. Consequently, contact elements, vias and the like of reduced lateral dimensions and with increased packing density may be provided in sophisticated applications on the basis of well-established etch chemistries.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming an opening in a dielectric material system formed above a substrate of a semiconductor device, said dielectric material system comprising at least a first dielectric layer and a second dielectric layer;
forming a first conductive barrier layer on inner sidewall surface areas in said opening;
increasing a depth of said opening so as to extend through said dielectric material system in the presence of said conductive barrier layer;
forming a second conductive barrier layer in said opening; and
filling said opening with a conductive material.

2. The method of claim 1, wherein forming said opening comprises providing an etch mask above said dielectric material system, etching through said second dielectric layer by using said etch mask and a first etch chemistry and using said first dielectric layer as an etch stop material.

3. The method of claim 2, wherein increasing a depth of said opening comprises etching through said first dielectric layer using a second etch chemistry that differs from said first etch chemistry.

4. The method of claim 1, wherein forming said first conductive barrier layer on inner sidewall surface areas of the opening comprises depositing said first conductive barrier layer and selectively removing a portion of said first conductive barrier layer from a bottom of said opening.

5. The method of claim 4 wherein said portion is removed by performing a sputter etch process.

6. The method of claim 1, further comprising performing a cleaning process after increasing a depth of said opening and prior to forming said second conductive barrier layer.

7. The method of claim 1, wherein said conductive barrier material is formed so as to connect to a contact region of a transistor.

8. The method of claim 1, wherein said conductive barrier material is formed so as to connect to a metal region of a metallization layer.

9. The method of claim 1, wherein said dielectric material system comprises a low-k dielectric material.

10. The method of claim 1, wherein said opening is formed with a critical lateral dimension at a top thereof of 100 nm or less.

11. The method of claim 1, further comprising forming a second opening in said dielectric material system so as to connect to said opening after forming said first conductive barrier layer and prior to forming said second conductive barrier layer, wherein said second opening extends to a reduced depth compared to said opening.

12. The method of claim 1, wherein said first and second conductive barrier layers comprises at least one of titanium and tantalum.

13. A method, comprising:
forming a conductive etch stop material on inner sidewall surfaces of an opening formed in a dielectric material system formed above a semiconductor layer of a semiconductor device;
increasing a depth of said opening by using said conductive etch stop material for preserving integrity of said inner sidewall surfaces; and
filling said opening with a metal-containing conductive material.

14. The method of claim 13, further comprising forming a conductive barrier material in said opening after increasing the depth thereof.

15. The method of claim 13, wherein forming said conductive etch stop layer comprises depositing a conductive material layer and removing a portion of said conductive material at a bottom of said opening.

16. The method of claim 13, further comprising forming said opening in at least a second dielectric layer of said dielectric material system and using a first dielectric layer of said dielectric material system as an etch stop layer.

17. The method of claim 13, wherein said metal-containing conductive material is formed so as to connect to a contact region of a transistor.

18. The method of claim 13, wherein said metal-containing conductive material is formed so as to extend to a metal region of a metallization layer.

19. A semiconductor device, comprising:
a dielectric material system comprising at least a first dielectric layer and a second dielectric layer formed above said first dielectric layer, said dielectric material system being formed above a device level comprising transistors having critical dimensions of approximately 50 nm or less; and
a conductive element extending through said dielectric material system, said conductive element comprising a first conductive barrier layer formed to be in direct contact with a portion of said second dielectric layer without extending to said first dielectric layer.

20. The semiconductor device of claim 19, wherein said conductive element connects to one of a contact region of one of said transistors and a metal region formed in a metallization layer of a metallization system.
